(19) United States
(12) Patent Application Publication
(10) Pub. No.: US 2026/0079206 A1
(43) Pub. Date: Mar. 19, 2026

(54) CONTROL DEVICE, ELECTRICAL APPLIANCE, AND FAULT DETECTION METHOD

(71) Applicants: Kabushiki Kaisha Toshiba, Tokyo (JP); Toshiba Electronic Devices & Storage Corporation, Tokyo (JP)

(72) Inventor: Motomichi SHIBANO, Atsugi Kanagawa (JP)

(21) Appl. No.: 19/065,359

(22) Filed: Feb. 27, 2025

(30) Foreign Application Priority Data
Sep. 13, 2024 (JP) 2024-159004

(51) Int. Cl. G01R 31/34; G01R 31/12; G01R 25/00

(52) U.S. Cl. CPC G01R 31/343; G01R 31/1272; G01R 25/005

(57) ABSTRACT

According to an embodiment, a control device includes a controller and a fault detector. The controller controls an electric motor. The fault detector detects a fault of the electric motor. The fault detector performs a frequency analysis of a voltage signal and a current signal that drive the electric motor. The fault detector determines, based on a result of the frequency analysis, whether or not the current signal includes an odd-order harmonic having a frequency that is odd multiples of a fundamental wave of the voltage signal. The fault detector determines, based on the result of the frequency analysis, whether or not the odd-order harmonic has a first phase angle that is a phase angle of an opposite phase with respect to a phase angle of the fundamental wave.

### CROSS-REFERENCE TO RELATED APPLICATION

This application is based upon and claims the benefit of priority from Japanese Patent Application No. 2024-159004, filed September 13, 2024; the entire contents of which are incorporated herein by reference.

### FIELD

Embodiments of the present invention relate to a control device, an electrical appliance, and a fault detection method.

### BACKGROUND

When insulation performance of an electric motor deteriorates, partial discharge that is a precursor phenomenon to insulation breakdown occurs. Detecting the partial discharge helps prevent the insulation breakdown from occurring in the electric motor previously. Since the partial discharge is buried in noise that accompanies the normal operation of the electric motor, it is necessary to detect the partial discharge by distinguishing it from the noise.

### BRIEF DESCRIPTION OF THE DRAWINGS

FIG. 1 is a diagram schematically showing a configuration example of an electrical appliance according to a first embodiment.

FIG. 2 is a functional block diagram showing functions of a fault detector in a control device according to the first embodiment.

FIG. 3 is a flowchart showing a fault detection process performed by the fault detector according to the first embodiment.

FIG. 4 is a diagram schematically showing a configuration example of an electrical appliance according to a second embodiment.

FIG. 5 is a functional block diagram showing functions of a fault detector in a control device according to the second embodiment.

FIG. 6 is a flowchart showing a fault detection process performed by the fault detector according to the second embodiment.

FIG. 7 is a diagram showing an example of a waveform in which partial discharge occurs with respect to a current signal with fundamental frequency of 50Hz.

FIG. 8 is a diagram showing a waveform of a signal obtained by performing band-pass filtering and envelope processing on the signal shown in FIG. 7.

FIG. 9 is a diagram showing a frequency analysis result of sinusoidal current signal including a partial discharge signal shown in FIG. 7.

FIG. 10 is a diagram showing a frequency analysis result of a signal shown in FIG. 8.

FIG. 11 is a diagram showing a discharge noise signal having a positive charge.

FIG. 12 is a diagram showing a waveform of a signal obtained by performing band-pass filtering and envelope processing on the signal shown in FIG. 11.

FIG. 13 is a diagram showing a frequency analysis result of sinusoidal current signal including the discharge noise signal shown in FIG. 11.

FIG. 14 is a diagram showing a frequency analysis result of a signal shown in FIG. 12.

FIG. 15 is a diagram showing a phase angle of each harmonic when the partial discharge signal is included in the sinusoidal current signal.

FIG. 16 is a diagram showing a phase angle of each harmonic when the discharge noise signal is included in the sinusoidal current signal.

FIG. 17 is a diagram schematically showing a first modification example of the electrical appliance.

FIG. 18 is a diagram schematically showing a second modification example of the electrical appliance.

### DETAILED DESCRIPTION

According to an embodiment, a control device includes a controller and a fault detector. The controller controls an electric motor. The fault detector detects a fault of the electric motor. The fault detector performs a frequency analysis of a voltage signal and a current signal that drive the electric motor. The fault detector determines, based on a result of the frequency analysis, whether or not the current signal includes an odd-order harmonic having a frequency that is odd multiples of a fundamental wave of the voltage signal. The fault detector determines, based on the result of the frequency analysis, whether or not the odd-order harmonic has a first phase angle that is a phase angle of an opposite phase with respect to a phase angle of the fundamental wave.

Hereinafter, control devices, electrical appliances, and fault detection methods of embodiments will be described with reference to the drawings.

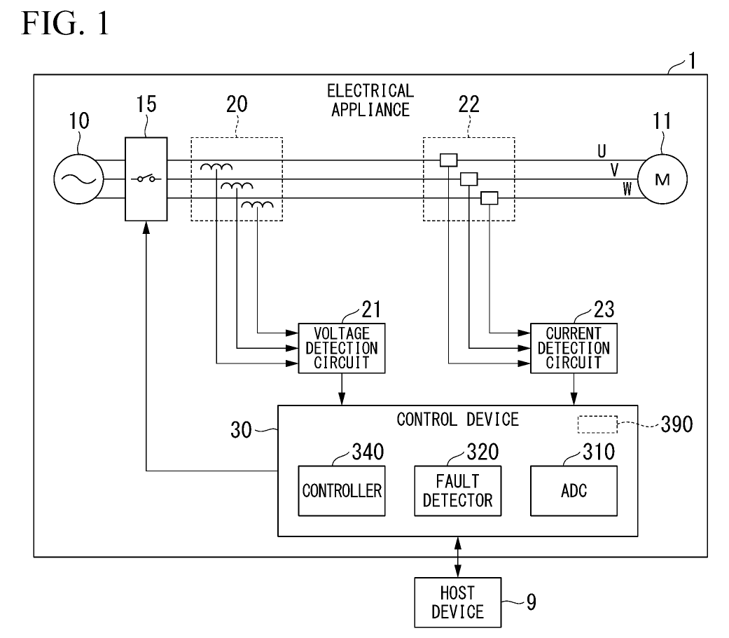

FIG. 1 is a diagram schematically showing a configuration example of an electrical appliance 1 according to a first embodiment. In FIG. 1, the electrical appliance 1 has a configuration for controlling a three-phase induction motor 11 using a three-phase AC power supply 10.

As shown in FIG. 1, the electrical appliance 1 includes the three-phase AC power supply 10, the three-phase induction motor 11, a switch 15, a voltage sensor circuit 20, a voltage detection circuit 21, a current sensor circuit 22, a current detection circuit 23, and a control device 30. The three-phase AC power supply 10 is an example of a power supply. The three-phase induction motor 11 is an example of an electric motor.

The three-phase AC power supply 10 is connected to the three-phase induction motor 11 by a three-phase connection. The three-phase AC power supply 10 supplies a three-phase AC electric signal including a U-phase signal, a V-phase signal, and a W-phase signal to the three-phase induction motor 11. The AC electric signal supplied from the three-phase AC power supply 10 to the three-phase induction motor 11 is an electric signal that drives the three-phase induction motor 11. The AC electric signal includes AC voltage signals and AC current signals. These AC voltage signals and AC current signals are an example of a voltage signal and a current signal that drive the electric motor. The three-phase AC power supply 10 may be an external component of the electrical appliance 1.

The three-phase induction motor 11 is driven by the AC electric signal from the three-phase AC power supply 10. The three-phase induction motor 11 is driven by receiving the three-phase AC electric signal via the three-phase connection. The three-phase induction motor 11 generates mechanical energy by the AC electric signal from the three-phase AC power supply 10. For example, an output shaft of the three-phase induction motor 11 is connected to a load device (not shown) and a drive device (not shown).

The switch 15 is provided between the three-phase AC power supply 10 and the three-phase induction motor 11. The switch 15 controls the supply of the AC electric signal from three-phase AC power supply 10 to the three-phase induction motor 11 under the control from the control device 30. For example, when a fault of the three-phase induction motor 11 is detected, the switch 15 cuts off the supply of the AC electric signal from three-phase AC power supply 10 to the three-phase induction motor 11.

The voltage sensor circuit 20 is connected to the three-phase connection. The voltage sensor circuit 20 senses a voltage supplied to each phase line forming the three-phase connection. For example, the voltage sensor circuit 20 includes a voltage sensor such as a voltage transformer (VT), as a voltage sensor for detecting each phase voltage.

The voltage detection circuit 21 is connected to the voltage sensor circuit 20. The voltage detection circuit 21 receives a voltage signal corresponding to the sensing result of each phase voltage from the voltage sensor circuit 20. The voltage detection circuit 21 detects a state of each phase voltage in the three-phase connection based on the sensing result of the voltage sensor circuit 20. The voltage detection circuit 21 has a function of converting the signal from the voltage sensor circuit 20 into a signal corresponding to an input voltage of an ADC 310 in the below-described control device 30.

The current sensor circuit 22 is connected to the three-phase connection. The current sensor circuit 22 senses a current (phase current) flowing through each phase line forming the three-phase connection. For example, the current sensor circuit 22 includes a current sensor such as a current transformer (CT), as a current sensor for detecting the phase current.

The current detection circuit 23 is connected to the current sensor circuit 22. The current detection circuit 23 receives a voltage signal corresponding to the sensing result of each phase current from the current sensor circuit 22. The current detection circuit 23 detects a state of each phase current in the three-phase connection based on the sensing result of the current sensor circuit 22. The current detection circuit 23 has a function of performing voltage conversion or impedance matching in order to apply the signal from the current sensor circuit 22 to an input of the below-described ADC 310.

The control device 30 controls an internal operation of the electrical appliance 1. In the electrical appliance 1 of the embodiment, the control device 30 includes the ADC (analog-digital convertor) 310, a fault detector 320, and a controller 340.

The ADC 310 converts various analog signals (analog values) detected within the electrical appliance 1 into digital signals (digital values). For example, the ADC 310 converts the signals from the voltage detection circuit 21 and the current detection circuit 23 into the digital signals. The signal input from the voltage detection circuit 21 to the ADC 310 is substantially the same as the AC voltage signal included in the AC electric signal driving the three-phase induction motor 11. Additionally, the signal input from the current detection circuit 23 to the ADC 310 is substantially the same as the AC current signal included in the AC electric signal driving the three-phase induction motor 11. Therefore, it can be said that the ADC 310 is a device that converts the AC voltage signal and the AC current signal driving the three-phase induction motor 11 into the digital signals.

The fault detector (also called a fault detection circuit) 320 detects a malfunction of the electrical appliance 1, such as a fault in the three-phase induction motor 11 or a defect in the three-phase AC power supply 10, based on various signals detected within the electrical appliance 1.

The controller (also called a control circuit) 340 monitors the operating state of each component in the electrical appliance 1 and controls the operation of each component. The controller 340 controls the functions and processing of the fault detector 320. The controller 340 is, for example, a processor.

In addition, the control device 30 may further include a memory 390. The memory 390 stores various data. For example, the memory 390 stores digital data indicating the sense results of the AC voltage signal and the AC current signal included in the AC electric signal driving the three-phase induction motor 11, as well as programs (software and applications) for controlling the three-phase induction motor 11.

The electrical appliance 1 of the embodiment has the three-phase AC power supply 10 as a drive source. The electrical appliance 1 controls the rotation of the three-phase induction motor 11 by the control device 30 while sensing the AC electric signal supplied from the three-phase AC power source 10 to the three-phase induction motor 11.

For example, when a fault such as an overcurrent, a short circuit, or a ground fault occurs in the three-phase induction motor 11, the electrical appliance 1 cuts off the supply of the AC electric signal from the three-phase AC power source 10 to the three-phase induction motor 11 using the switch 15 based on instructions from the control device 30. For example, when an abnormality such as a phase loss, imbalance, dip or swell occurs in the three-phase AC power supply 10, the electrical appliance 1 protects the three-phase induction motor 11 by cutting-off operation of the switch 15 based on the instructions from the control device 30.

The electrical appliance 1 of the embodiment communicates with a host device 9 such as a PLC (Programmable Logic Controller). The host device 9 communicates with the control devices 30 of a plurality of the electrical appliances 1. The host device 9 monitors the operating state of the electrical appliance 1 based on the result of the communication. For example, the host device 9 monitors the regular power consumption and the status signal obtained in real time from the fault detector 320, etc. Thereby, the host device 9 grasps the state of the three-phase induction motor 11 in the electrical appliance 1 and the state of the load device (not shown).

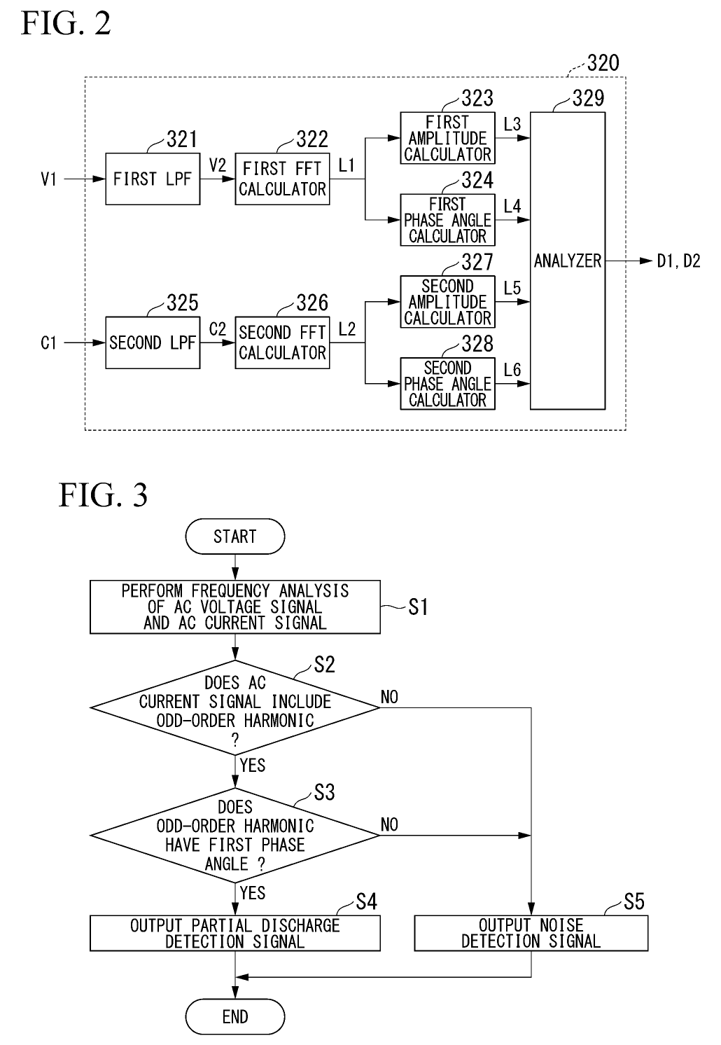

FIG. 2 is a functional block diagram showing functions of the fault detector 320 in the control device 30 according to the first embodiment. In FIG. 2, an example of the configuration of a signal calculator for a one-phase AC electric signal out of a three-phase system is shown. Substantially the same operations are performed on the other phases of the AC electric signals.

The fault detector 320 includes one or more calculators (processors) configured by a micro-controller unit (MCU) or an ASIC (Application Specific Integrated Circuit). The fault detector 320 may use data and a program in the memory 390.

As shown in FIG. 2, the fault detector 320 includes, as functional blocks, a first LPF (Low Pass Filter) 321, a first FFT (Fast Fourier Transform) calculator 322, a first amplitude calculator 323, a first phase angle calculator 324, a second LPF 325, a second FFT calculator 326, a second amplitude calculator 327, a second phase angle calculator 328, and an analyzer 329. The functions of the fault detector 320 shown by these functional blocks may be realized by hardware or may be realized by one or more processors executing a program.

As described above, the ADC 310 converts the AC voltage signal and the AC current signal driving the three-phase induction motor 11 into the digital signals. Hereinafter, the AC voltage signal converted into the digital signal may be referred to as a “first voltage signal V1”, and the AC current signal converted into the digital signal may be referred to as a “first current signal C1”. The first voltage signal V1 is input to the first LPF 321. The first current signal C1 is input to the second LPF 325.

The first LPF 321 is a digital low-pass filter that extracts, from the first voltage signal V1, a second voltage signal V2 including frequency components equal to or lower than a first cutoff frequency. The first LPF 321 outputs the second voltage signal V2 to the first FFT calculator 322.

The second LPF 325 is a digital low-pass filter that extracts, from the first current signal C1, a second current signal C2 including frequency components equal to or lower than a second cutoff frequency. The second LPF 325 outputs the second current signal C2 to the second FFT calculator 326. The second cutoff frequency may be the same as the first cutoff frequency or may differ from the first cutoff frequency.

The band of the AC electric signal processed in the fault detector 320 is limited to a band for monitoring the state of the three-phase induction motor 11 by the first LPF 321 and the second LPF 325. Thereby, it is possible to block harmonic noise and disturbance noise contained in the AC electric signal that drives the three-phase induction motor 11. In order to improve the SN ratio of the AC electric signal processed in the fault detector 320, a decimation filter may be used as the first LPF 321 and the second LPF 325.

The first FFT calculator 322 performs a fast Fourier transform based on the second voltage signal V2 output from the first LPF 321. The first FFT calculator 322 generates, as a result of the fast Fourier transform based on the second voltage signal V2, a list that indicates the correspondence between the frequencies of the multiple sine waves contained in the second voltage signal V2 and complex numbers that represent these sine waves in polar coordinate format. Hereinafter, the list generated by the first FFT calculator 322 may be referred to as a “first frequency list L1”. The first FFT calculator 322 outputs the first frequency list L1 to the first amplitude calculator 323 and the first phase angle calculator 324.

The second FFT calculator 326 performs a fast Fourier transform based on the second current signal C2 output from the second LPF 325. The second FFT calculator 326 generates, as a result of the fast Fourier transform based on the second current signal C2, a list that indicates the correspondence between the frequencies of the multiple sine waves contained in the second current signal C2 and complex numbers that represent these sine waves in polar coordinate format. Hereinafter, the list generated by the second FFT calculator 326 may be referred to as a “second frequency list L2”. The second FFT calculator 326 outputs the second frequency list L2 to the second amplitude calculator 327 and the second phase angle calculator 328.

The first FFT calculator 322 and the second FFT calculator 326 may be implemented by software or by a hardware accelerator. When the three-phase induction motor 11 is driven at a commercial frequency, it is desirable to obtain the AC electric signal having 10 to 12 cycles and perform a fast Fourier transform.

The first amplitude calculator 323 calculates, based on the first frequency list L1 output from the first FFT calculator 322, an amplitude of each sin wave included in the second voltage signal V2. As is well known, the amplitude of a sine wave can be calculated by calculating the square root of the sum of the squares of the real part and the imaginary part contained in a complex number. The first amplitude calculator 323 outputs a first amplitude list L3 that is a list indicating correspondence between the frequency of each sin wave included in the second voltage signal V2 and the amplitude of each sin wave, to the analyzer 329.

The first phase angle calculator 324 calculates, based on the first frequency list L1 output from the first FFT calculator 322, a phase angle of each sin wave included in the second voltage signal V2. As is well known, the phase angle of a sine wave can be calculated by calculating the arctangent using the real and imaginary parts contained in a complex number. The first phase angle calculator 324 outputs a first phase angle list L4 that is a list indicating correspondence between the frequency of each sin wave included in the second voltage signal V2 and the phase angle of each sin wave, to the analyzer 329.

The second amplitude calculator 327 calculates, based on the second frequency list L2 output from the second FFT calculator 326, an amplitude of each sin wave included in the second current signal C2. The second amplitude calculator 327 outputs a second amplitude list L5 that is a list indicating correspondence between the frequency of each sin wave included in the second current signal C2 and the amplitude of each sin wave, to the analyzer 329.

The second phase angle calculator 328 calculates, based on the second frequency list L2 output from the second FFT calculator 326, a phase angle of each sin wave included in the second current signal C2. The second phase angle calculator 328 outputs a second phase angle list L6 that is a list indicating correspondence between the frequency of each sin wave included in the second current signal C2 and the phase angle of each sin wave, to the analyzer 329.

Among the functions of the fault detector 320, the first LPF 321, the first FFT calculator 322, the first amplitude calculator 323, the first phase angle calculator 324, the second LPF 325, the second FFT calculator 326, the second amplitude calculator 327, and the second phase angle calculator 328 are functions performing a frequency analysis of the AC voltage signal and the AC current signal that drive the three-phase induction motor 11. The first amplitude list L3, the first phase angle list L4, the second amplitude list L5, and the second phase angle list L6 are results of the frequency analysis of the AC voltage signal and the AC current signal. Hereinafter, the first amplitude list L3, the first phase angle list L4, the second amplitude list L5, and the second phase angle list L6 may be referred to as a “first analysis result”.

The analyzer 329 analyzes the state of the three-phase induction motor 11 based on the first analysis result. More specifically, the analyzer 329 determines, based on the first analysis result, whether or not the AC current signal includes an odd-order harmonic having a frequency that is odd multiples of a fundamental wave of the AC voltage signal. For example, in the present embodiment, the odd-order harmonic is a third-order harmonic having a frequency that is three multiples of the fundamental wave of the AC voltage signal. For example, the analyzer 329 obtains the frequency associated with the largest amplitude in the first amplitude list L3 as the frequency of the fundamental wave of the AC voltage signal. Then, the analyzer 329 determines that the AC current signal includes the third-order harmonic if the amplitude associated with a frequency three times the fundamental frequency of the AC voltage signal in the second amplitude list L5 is greater than or equal to a predetermined threshold value.

Additionally, the analyzer 329 determines, based on the first analysis result, whether or not the odd-order harmonic (third-order harmonic) included in the AC current signal has a first phase angle that is a phase angle of an opposite phase with respect to a phase angle of the fundamental wave of the AC voltage signal. For example, in the present embodiment, the first phase angle is a phase angle of ±90 degrees or more with respect to the phase angle of the fundamental wave. For example, the analyzer 329 obtains a phase angle associated with the frequency of the fundamental wave in the first phase angle list L4 as the phase angle of the fundamental wave. Then, the analyzer 329 determines that the odd-order harmonic (third-order harmonic) included in the AC current signal has the first phase angle if the phase angle associated with the frequency three times the fundamental frequency in the second phase angle list L6 is a phase angle of ±90 degrees or more with respect to the phase angle of the fundamental wave.

When the odd-order harmonic (third-order harmonic) included in the AC current signal has the first phase angle, the analyzer 329 outputs a partial discharge notification signal D1 indicating that a partial discharge in the three-phase induction motor 11 has been detected. When the AC current signal does not include the odd-order harmonic or the odd-order harmonic does not have the first phase angle, the analyzer 329 outputs a noise detection signal D2 indicating that the disturbance noise has been detected.

When the partial discharge occurs in the three-phase induction motor 11, a signal generated due to the partial discharge appears as an odd-order harmonic, which has a frequency that is odd multiples of the fundamental wave of the AC voltage signal, among the harmonics included in the AC current signal. Therefore, if the AC current signal includes odd-order harmonics, it is assumed that the partial discharge has occurred in the three-phase induction motor 11. However, when odd-order harmonic noise generated due to mechanical vibration or odd-order harmonic noise generated from the three-phase AC power supply 10 is mixed into the AC current signal, it is not possible to distinguish whether the odd-order harmonic included in the AC current signal is a harmonic due to the partial discharge or a harmonic due to the above-mentioned disturbance noise. Therefore, in this embodiment, the fault detector 320 has a function of determining whether or not the odd-order harmonic included in the AC current signal has the first phase angle that is a phase angle of an opposite phase with respect to the phase angle of the fundamental wave of the AC voltage signal. When the partial discharge occurs in the three-phase induction motor 11, a signal generated due to the partial discharge appears as an odd-order harmonic having a first phase angle that is a phase angle of an opposite phase with respect to a phase angle of the fundamental wave of the AC voltage signal. Therefore, the fault detector 320 not only determines whether or not the AC current signal includes the odd-order harmonic but also determines whether or not the odd-order harmonic included in the AC current signal has the first phase angle, making it possible to detect the partial discharge in distinction from the above-mentioned disturbance noise.

FIG. 3 is a flowchart showing a fault detection process performed by the fault detector 320. The fault detection process explained below may be realized by one of hardware and software, or a combination of hardware and software. In the present embodiment, the fault detector 320 performs the fault detection process, thereby the fault detection method is realized.

As shown in FIG. 3, the fault detector 320 performs a frequency analysis of the AC voltage signal and the AC current signal that drive the three-phase induction motor 11 (step S1). Specifically, in step S1, the fault detector 320 performs processes as follows.

The fault detector 320 extracts, from the first voltage signal V1 that is the AC voltage signal converted into the digital signal, the second voltage signal V2 including frequency components equal to or lower than the first cutoff frequency. The fault detector 320 extracts, from the first current signal C1 that is the AC current signal converted into the digital signal, the second current signal C2 including frequency components equal to or lower than the second cutoff frequency.

The fault detector 320 performs the fast Fourier transform based on the second voltage signal V2 to generate the first frequency list L1 that indicates the correspondence between the frequencies of the multiple sine waves contained in the second voltage signal V2 and complex numbers that represent these sine waves in polar coordinate format.

The fault detector 320 performs the fast Fourier transform based on the second current signal C2 to generate the second frequency list L2 that indicates the correspondence between the frequencies of the multiple sine waves contained in the second current signal C2 and complex numbers that represent these sine waves in polar coordinate format.

The fault detector 320 calculates, based on the first frequency list L1, an amplitude of each sin wave included in the second voltage signal V2 to generate the first amplitude list L3 indicating correspondence between the frequency of each sin wave included in the second voltage signal V2 and the amplitude of each sin wave.

The fault detector 320 calculates, based on the first frequency list L1, a phase angle of each sin wave included in the second voltage signal V2 to generate the first phase angle list L4 indicating correspondence between the frequency of each sin wave included in the second voltage signal V2 and the phase angle of each sin wave.

The fault detector 320 calculates, based on the second frequency list L2, an amplitude of each sin wave included in the second current signal C2 to generate the second amplitude list L5 indicating correspondence between the frequency of each sin wave included in the second current signal C2 and the amplitude of each sin wave.

The fault detector 320 calculates, based on the second frequency list L2, a phase angle of each sin wave included in the second current signal C2 to generate the second phase angle list L6 indicating correspondence between the frequency of each sin wave included in the second current signal C2 and the phase angle of each sin wave.

Since the above-described processes of step S1 are the same as the processes performed by the first LPF 321, the first FFT calculator 322, the first amplitude calculator 323, the first phase angle calculator 324, the second LPF 325, the second FFT calculator 326, the second amplitude calculator 327, and the second phase angle calculator 328, the detailed explanations thereof are omitted here. The fault detector 320 performs the above-described processes of step S1 to obtain the first amplitude list L3, the first phase angle list L4, the second amplitude list L5, and the second phase angle list L6 as the first analysis result.

Next, the fault detector 320 determines, based on the first analysis result, whether or not the AC current signal includes an odd-order harmonic having a frequency that is odd multiples of a fundamental wave of the AC voltage signal (step S2). As described above, for example, in the present embodiment, the odd-order harmonic is a third-order harmonic having a frequency that is three multiples of the fundamental wave of the AC voltage signal.

When the AC current signal includes the odd-order harmonic (step S2: YES), the fault detector 320 determines, based on the first analysis result, whether or not the odd-order harmonic (third-order harmonic) included in the AC current signal has a first phase angle that is a phase angle of an opposite phase with respect to a phase angle of the fundamental wave of the AC voltage signal (step S3). As described above, in the present embodiment, the first phase angle is a phase angle of ±90 degrees or more with respect to the phase angle of the fundamental wave.

Then, when the odd-order harmonic (third-order harmonic) included in the AC current signal has the first phase angle (step S3: YES), the fault detector 320 outputs a partial discharge notification signal D1 indicating that a partial discharge in the three-phase induction motor 11 has been detected (step S4).

On the other hand, when the AC current signal does not include the odd-order harmonic (step S2: NO), the fault detector 320 outputs a noise detection signal D2 indicating that the disturbance noise has been detected (step S5). Even if the AC current signal includes the odd-order harmonic, when the odd-order harmonic does not have the first phase angle (step S3: NO), the fault detector 320 outputs the noise detection signal D2 (step S5). Since the processes of step S2 to step S5 are the same as the processes performed by the analyzer 329, the detailed explanations thereof are omitted here.

As described above, the control device 30 of the first embodiment includes the controller 340 and the fault detector 320. The controller 340 controls the three-phase induction motor 11. The fault detector 320 detects a fault of the three-phase induction motor 11. The fault detector 320 performs a frequency analysis of the AC voltage signal and the AC current signal that drive the three-phase induction motor 11. The fault detector 320 determines, based on the first analysis result, whether or not the AC current signal includes an odd-order harmonic (third-order harmonic) having a frequency that is odd multiples of a fundamental wave of the AC voltage signal. The fault detector 320 determines, based on the first analysis result, whether or not the odd-order harmonic included in the AC current signal has a first phase angle that is a phase angle of an opposite phase with respect to a phase angle of the fundamental wave.

According to the above-described control device 30 of the first embodiment, the fault detector 320 not only determines whether or not the AC current signal includes the odd-order harmonic but also determines whether or not the odd-order harmonic included in the AC current signal has the first phase angle, making it possible to detect partial discharges in distinction from odd-order harmonic noise mixed into the AC current signal.

The fault detection method includes performing a frequency analysis of the AC voltage signal and the AC current signal that drive the three-phase induction motor 11 (step S1), determining, based on the first analysis result, whether or not the AC current signal includes an odd-order harmonic having a frequency that is odd multiples of a fundamental wave of the AC voltage signal (step S2), and determining, based on the first analysis result, whether or not the odd-order harmonic included in the AC current signal has a first phase angle that is a phase angle of an opposite phase with respect to a phase angle of the fundamental wave (step S3).

According to the above-described fault detection method, the fault detection method includes not only determining whether or not the AC current signal includes the odd-order harmonic but also determining whether or not the odd-order harmonic included in the AC current signal has the first phase angle, making it possible to detect partial discharges in distinction from odd-order harmonic noise mixed into the AC current signal.

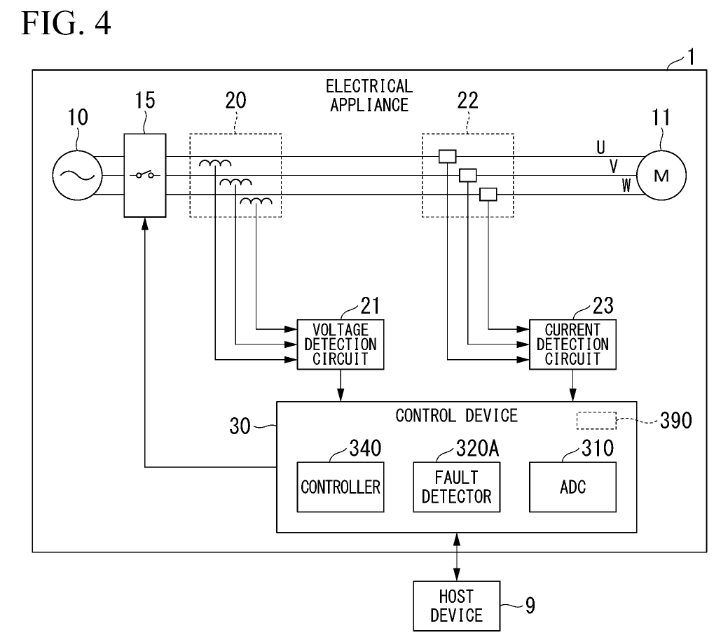

FIG. 4 is a diagram schematically showing a configuration example of an electrical appliance 1 according to a second embodiment. The electrical appliance 1 of the second embodiment differs from the electrical appliance 1 of the first embodiment in that the control device 30 includes a fault detector 320A in which additional functions are implemented in the fault detector 320. Hereinafter, the fault detector 320A, which is a difference between the first embodiment and the second embodiment, will be described in detail. The other components are denoted by the same reference numerals as in the first embodiment, and the description thereof will be omitted or simplified.

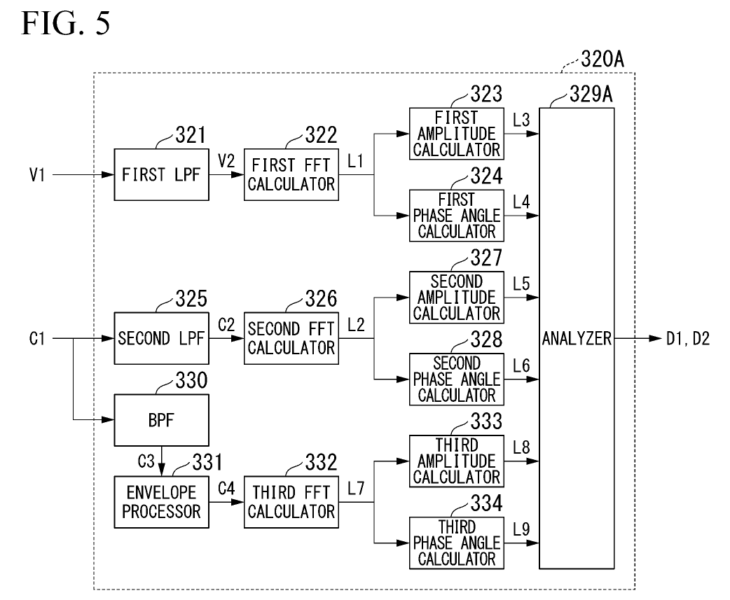

FIG. 5 is a functional block diagram showing functions of the fault detector 320A in the control device 30 according to the second embodiment. In FIG. 5, an example of the configuration of a signal calculator for a one-phase AC electric signal out of a three-phase system is shown. Substantially the same operations are performed on the other phases of the AC electric signals.

Similar to the fault detector 320 of the first embodiment, the fault detector 320A includes one or more calculators (processors) configured by a micro-controller unit (MCU) or an ASIC. The fault detector 320A may use data and a program in the memory 390.

As shown in FIG. 5, the fault detector 320A includes, as functional blocks, the first LPF 321, the first FFT calculator 322, the first amplitude calculator 323, the first phase angle calculator 324, the second LPF 325, the second FFT calculator 326, the second amplitude calculator 327, and the second phase angle calculator 328. Since these functional blocks are the same as those in the first embodiment, the description thereof will be omitted.

The fault detector 320A further includes, as functional blocks, a BPF (Band Pass Filter) 330, an envelope processor 331, a third FFT calculator 332, a third amplitude calculator 333, a third phase angle calculator 334. The fault detector 320A includes, as a functional block, an analyzer 329A in which additional functions are added to the analyzer 329. The functions of the fault detector 320A shown by these functional blocks may be realized by hardware or may be realized by one or more processors executing a program.

In the fault detector 320A, the first current signal C1, which is the AC current signal converted into the digital signal, is input to not only the second LPF 325 but also the BPF 330. The BPF 330 is a digital band-pass filter that extracts a third current signal C3 in a first frequency band from the first current signal C1. For example, in this embodiment, in order to obtain a partial discharge waveform in a low frequency range, the BPF 330 having a center frequency of about 100kHz is used. The BPF 330 outputs the third current signal C3 to the envelope processor 331. The third current signal C3 is one example of a first signal.

The envelope processor 331 generates a fourth current signal C4 by performing envelope processing on the third current signal C3 output from the BPF 330. The envelope processor 331 outputs the fourth current signal C4 to the third FFT calculator 332. The fourth current signal C4 is one example of a second signal.

The third FFT calculator 332 performs a fast Fourier transform based on the fourth current signal C4 output from the envelope processor 331. The third FFT calculator 332 generates, as a result of the fast Fourier transform based on the fourth current signal C4, a list that indicates the correspondence between the frequencies of the multiple sine waves contained in the fourth current signal C4 and complex numbers that represent these sine waves in polar coordinate format. Hereinafter, the list generated by the third FFT calculator 332 may be referred to as a “third frequency list L7”. The third FFT calculator 332 outputs the third frequency list L7 to the third amplitude calculator 333 and the third phase angle calculator 334.

The third amplitude calculator 333 calculates, based on the third frequency list L7 output from the third FFT calculator 332, an amplitude of each sin wave included in the fourth current signal C4. The third amplitude calculator 333 outputs a third amplitude list L8 that is a list indicating correspondence between the frequency of each sin wave included in the fourth current signal C4 and the amplitude of each sin wave, to the analyzer 329A.

The third phase angle calculator 334 calculates, based on the third frequency list L7 output from the third FFT calculator 332, a phase angle of each sin wave included in the fourth current signal C4. The third phase angle calculator 334 outputs a third phase angle list L9 that is a list indicating correspondence between the frequency of each sin wave included in the fourth current signal C4 and the phase angle of each sin wave, to the analyzer 329A.

Among the functions of the fault detector 320A, the third FFT calculator 332, the third amplitude calculator 333, and the third phase angle calculator 334 are functions performing a frequency analysis of the fourth current signal C4 (the second signal). The third amplitude list L8 and the third phase angle list L9 are results of the frequency analysis of the fourth current signal C4. Hereinafter, the third amplitude list L8 and the third phase angle list L9 may be referred to as a “second analysis result”.

The analyzer 329A analyzes the state of the three-phase induction motor 11 based on the first analysis result and the second analysis result. More specifically, similar to the analyzer 329 of the first embodiment, the analyzer 329A determines, based on the first analysis result, whether or not the AC current signal includes an odd-order harmonic having a frequency that is odd multiples of a fundamental wave of the AC voltage signal. For example, in the present embodiment, the odd-order harmonic is a third-order harmonic having a frequency that is three multiples of the fundamental wave of the AC voltage signal.

Additionally, similar to the analyzer 329 of the first embodiment, the analyzer 329A determines, based on the first analysis result, whether or not the odd-order harmonic (third-order harmonic) included in the AC current signal has a first phase angle that is a phase angle of an opposite phase with respect to a phase angle of the fundamental wave of the AC voltage signal. For example, in the present embodiment, the first phase angle is a phase angle of ±90 degrees or more with respect to the phase angle of the fundamental wave.

The analyzer 329A determines, based on the second analysis result, whether or not the fourth current signal C4 includes an even-order harmonic having a frequency that is even multiples of the fundamental wave of the AC voltage signal. For example, in the present embodiment, the even-order harmonic is a second-order harmonic having a frequency that is two multiples of the fundamental wave of the AC voltage signal. For example, the analyzer 329A determines that the fourth current signal C4 includes the second-order harmonic if the amplitude associated with a frequency two times the fundamental frequency of the AC voltage signal in the third amplitude list L8 is greater than or equal to a predetermined threshold value.

The analyzer 329A determines, based on the second analysis result, whether or not the even-order harmonic (second-order harmonic) included in the fourth current signal C4 has a second phase angle that is a phase angle of the same phase with respect to the phase angle of the fundamental wave of the AC voltage signal. For example, in the present embodiment, the second phase angle is a phase angle less than ±90 degrees with respect to the phase angle of the fundamental wave. For example, the analyzer 329A determines that the even-order harmonic (second-order harmonic) included in the fourth current signal C4 has the second phase angle if the phase angle associated with the frequency two times the fundamental frequency in the third phase angle list L9 is less than a phase angle of ±90 degrees with respect to the phase angle of the fundamental wave.

When the odd-order harmonic (third-order harmonic) included in the AC current signal has the first phase angle and the even-order harmonic (second-order harmonic) included in the fourth current signal C4 has the second phase angle, the analyzer 329A outputs a partial discharge notification signal D1 indicating that a partial discharge in the three-phase induction motor 11 has been detected. In cases other than those mentioned above, the analyzer 329A outputs a noise detection signal D2 indicating that the disturbance noise has been detected.

Similar to the first embodiment, the fault detector 320A not only determines whether or not the AC current signal includes the odd-order harmonic but also determines whether or not the odd-order harmonic included in the AC current signal has the first phase angle, making it possible to detect the partial discharge in distinction from the odd-order harmonic noise mixed into the AC current signal. However, when the odd-order harmonic noise having the first phase angle is mixed into the AC current signal, it is not possible to distinguish whether the odd-order harmonic included in the AC current signal is a harmonic caused by the partial discharge or a harmonic caused by the above-mentioned disturbance noise. Therefore, in this embodiment, the fault detector 320A has a function of determining whether or not the even-order harmonic included in the fourth current signal C4 (second signal) obtained by performing band-pass filtering and envelope processing on the AC current signal have the second phase angle that is a phase angle of the same phase with respect to the phase angle of the fundamental wave of the AC voltage signal. When the partial discharge occurs in the three-phase induction motor 11, a signal generated due to the partial discharge appears in the fourth current signal C4 as an even-order harmonic having the second phase angle that is a phase angle of the same phase with respect to the phase angle of the fundamental wave of the AC voltage signal. Therefore, the fault detector 320A not only determines whether or not the odd-order harmonic (third-order harmonic) included in the AC current signal has the first phase angle but also determines whether or not the even-order harmonic (second-order harmonic) included in the fourth current signal C4 has the second phase angle, making it possible to detect the partial discharge in distinction from the above-mentioned disturbance noise.

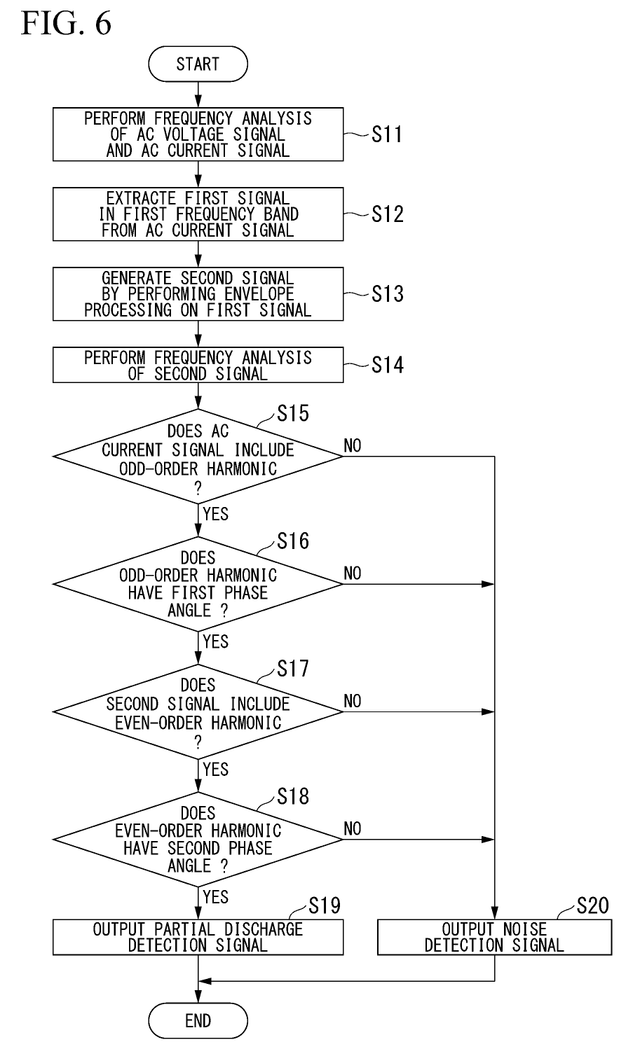

FIG. 6 is a flowchart showing a fault detection process performed by the fault detector 320A. The fault detection process explained below may be realized by one of hardware and software, or a combination of hardware and software.

As shown in FIG. 6, the fault detector 320A performs a frequency analysis of the AC voltage signal and the AC current signal that drive the three-phase induction motor 11 (step S11). Since the process performed by the failure detector 320A in step S11 is the same as the process performed by the failure detector 320 in the first embodiment in step S1, the detailed description of the process in step S11 will be omitted. The fault detector 320A performs the above-described processes of step S11 to obtain the first amplitude list L3, the first phase angle list L4, the second amplitude list L5, and the second phase angle list L6 as the first analysis result.

Next, the fault detector 320A extracts the third current signal C3 in the first frequency band from the first current signal C1 that is the AC current signal converted into the digital signal (step S12). Since the process of step S12 is the same as the process performed by the BPF 330, the detailed explanations thereof are omitted here.

Next, the fault detector 320A generates the fourth current signal C4 (second signal) by performing envelope processing on the third current signal C3 (step S13). Since the process of step S13 is the same as the process performed by the envelope processor 331, the detailed explanations thereof are omitted here.

Next, the fault detector 320A performs a frequency analysis of the fourth current signal C4 (second signal) (step S14). Specifically, in step S14, the fault detector 320A performs the following processes.

The fault detector 320A performs a fast Fourier transform based on the fourth current signal C4 to generate the third frequency list L7 that indicates the correspondence between the frequencies of the multiple sine waves contained in the fourth current signal C4 and complex numbers that represent these sine waves in polar coordinate format.

The fault detector 320A calculates, based on the third frequency list L7, an amplitude of each sin wave included in the fourth current signal C4 to generate the third amplitude list L8 that indicates the correspondence between the frequency of each sin wave included in the fourth current signal C4 and the amplitude of each sin wave.

The fault detector 320A calculates, based on the third frequency list L7, a phase angle of each sin wave included in the fourth current signal C4 to generate the third phase angle list L9 that indicates the correspondence between the frequency of each sin wave included in the fourth current signal C4 and the phase angle of each sin wave.

Since the above-described processes of step S14 are the same as the processes performed by the third FFT calculator 332, the third amplitude calculator 333, and the third phase angle calculator 334, the detailed explanations thereof are omitted here. The fault detector 320A performs the above-described processes of step S14 to obtain the third amplitude list L8 and the third phase angle list L9 as the second analysis result.

Next, the fault detector 320A determines, based on the first analysis result, whether or not the AC current signal includes an odd-order harmonic having a frequency that is odd multiples of a fundamental wave of the AC voltage signal (step S15). As described above, for example, in the present embodiment, the odd-order harmonic is a third-order harmonic having a frequency that is three multiples of the fundamental wave of the AC voltage signal.

When the AC current signal includes the odd-order harmonic (step S15: YES), the fault detector 320A determines, based on the first analysis result, whether or not the odd-order harmonic (third-order harmonic) included in the AC current signal has a first phase angle that is a phase angle of an opposite phase with respect to a phase angle of the fundamental wave of the AC voltage signal (step S16). As described above, for example, in the present embodiment, the first phase angle is a phase angle of ±90 degrees or more with respect to the phase angle of the fundamental wave.

When the odd-order harmonic (third-order harmonic) included in the AC current signal has the first phase angle (step S16: YES), the fault detector 320A determines, based on the second analysis result, whether or not the fourth current signal C4 (second signal) includes an even-order harmonic having a frequency that is even multiples of the fundamental wave of the AC voltage signal (step S17). As described above, for example, in the present embodiment, the even-order harmonic is a second-order harmonic having a frequency that is two multiples of the fundamental wave of the AC voltage signal.

When the fourth current signal C4 includes the even-order harmonic (step S17: YES), the fault detector 320A determines, based on the second analysis result, whether or not the even-order harmonic (second-order harmonic) included in the fourth current signal C4 has a second phase angle that is a phase angle of the same phase with respect to the phase angle of the fundamental wave of the AC voltage signal (step S18). As described above, for example, in the present embodiment, the second phase angle is a phase angle less than ±90 degrees with respect to the phase angle of the fundamental wave.

Then, when the even-order harmonic (second-order harmonic) included in the fourth current signal C4 has the second phase angle (step S18: YES), the fault detector 320A outputs a partial discharge notification signal D1 indicating that a partial discharge in the three-phase induction motor 11 has been detected (step S19).

On the other hand, when the AC current signal does not include the odd-order harmonic (step S15: NO), the fault detector 320A outputs a noise detection signal D2 indicating that the disturbance noise has been detected (step S20). Even if the AC current signal includes the odd-order harmonic, when the odd-order harmonic does not have the first phase angle (step S16: NO), the fault detector 320A outputs the noise detection signal D2 (step S20). Even if the AC current signal includes the odd-order harmonic having the first phase angle, when the fourth current signal C4 does not include the even-order harmonic (step S17: NO), the fault detector 320A outputs the noise detection signal D2 (step S20). Even if the AC current signal includes the odd-order harmonic having the first phase angle and the fourth current signal C4 includes the even-order harmonic, when the even-order harmonic does not have the second phase angle (step S18: NO), the fault detector 320A outputs the noise detection signal D2 (step S20). Since the processes of step S15 to step S20 are the same as the processes performed by the analyzer 329A, the detailed explanations thereof are omitted here.

As described above, the control device 30 of the second embodiment includes the controller 340 and the fault detector 320A. The controller 340 controls the three-phase induction motor 11. The fault detector 320A detects a fault of the three-phase induction motor 11. The fault detector 320A performs a frequency analysis of the AC voltage signal and the AC current signal that drive the three-phase induction motor 11. The fault detector 320A determines, based on the first analysis result, whether or not the AC current signal includes an odd-order harmonic (third-order harmonic) having a frequency that is odd multiples of a fundamental wave of the AC voltage signal. The fault detector 320A determines, based on the first analysis result, whether or not the odd-order harmonic included in the AC current signal has a first phase angle that is a phase angle of an opposite phase with respect to a phase angle of the fundamental wave. The fault detector 320A extracts the first signal (third current signal C3) in the first frequency band from the AC current signal. The fault detector 320A generates the second signal (fourth current signal C4) by performing envelope processing on the first signal. The fault detector 320A performs a frequency analysis of the second signal. The fault detector 320A determines, based on the second analysis result, whether or not the second signal includes an even-order harmonic having a frequency that is even multiples of the fundamental wave. The fault detector 320A determines, based on the second analysis result, whether or not the even-order harmonic included in the second current signal has a second phase angle that is a phase angle of the same phase with respect to the phase angle of the fundamental wave.

According to the second embodiment, the fault detector 320A not only determines whether or not the odd-order harmonic (third-order harmonic) included in the AC current signal has the first phase angle but also determines whether or not the even-order harmonic (second-order harmonic) included in the second signal (fourth current signal C4) has the second phase angle, making it possible to detect partial discharges in distinction from odd-order harmonic noise having the first phase angle.

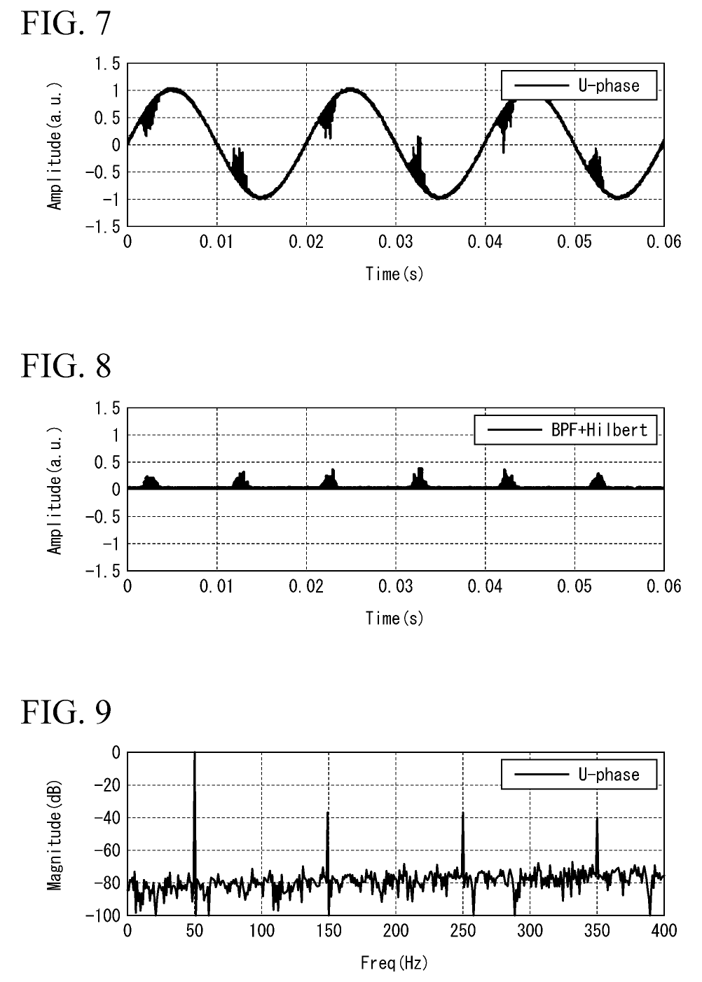

FIGS. 7 to 16 show the results of analysis using simulation waveforms in order to clarify the effects of the above embodiments. FIG. 7 is a diagram showing an example of a waveform in which partial discharge occurs with respect to a current signal with fundamental frequency of 50Hz. The partial discharge waveform has a half-width of several micro second and simulates a phenomenon occurring at positions of 45 degrees and 225 degrees relative to the phase of the power fundamental wave. FIG. 8 is a diagram showing a waveform of a signal obtained by performing band-pass filtering and envelope processing on the signal shown in FIG. 7.

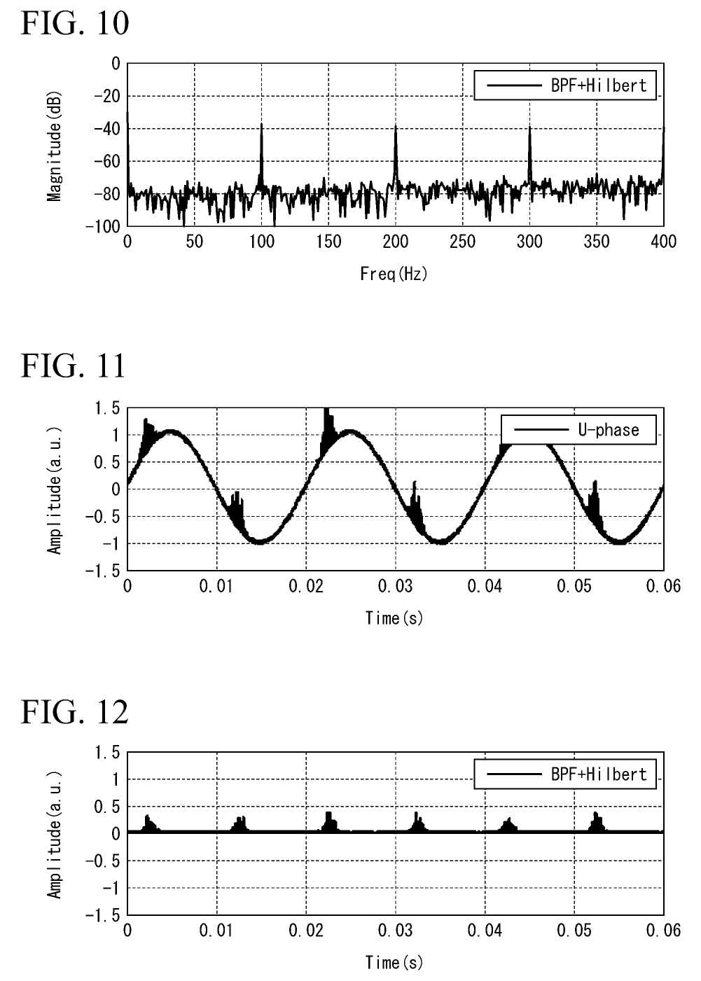

FIG. 9 is a diagram showing a frequency analysis result of sinusoidal current signal including a partial discharge signal shown in FIG. 7. FIG. 10 is a diagram showing a frequency analysis result of a signal shown in FIG. 8. As shown in FIG. 9, partial discharge signals appear as odd-order harmonics such as third-order harmonics, fifth-order harmonics, etc. with respect to the power fundamental frequency (50Hz). On the other hand, as shown in FIG. 10, in the signal obtained by performing band-pass filtering and envelope processing on the sinusoidal current signal, the partial discharge signals appear as even-order harmonics such as second-order harmonics, fourth-order harmonics, etc. with respect to the power fundamental frequency.

To compare the condition of the sinusoidal current waveform including the partial discharge signal shown in FIG. 7, a discharge noise signal having a positive charge is shown in FIG. 11. A partial discharge signal generates a current relative to the ground potential, but a current having a certain charge is added as a disturbance noise. FIG. 12 is a diagram showing a waveform of a signal obtained by performing band-pass filtering and envelope processing on the signal shown in FIG. 11.

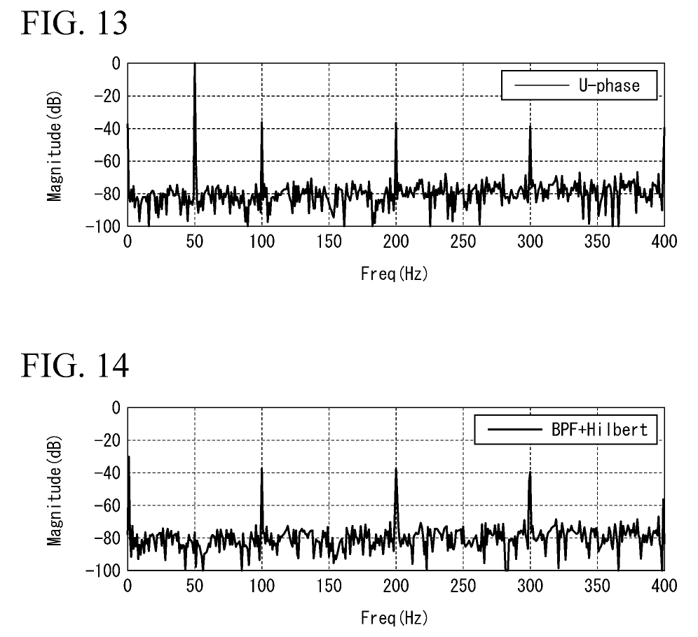

FIG. 13 is a diagram showing a frequency analysis result of sinusoidal current signal including the discharge noise signal shown in FIG. 11. FIG. 14 is a diagram showing a frequency analysis result of a signal shown in FIG. 12. As shown in FIG. 13, the discharge noise signal appears as even-order harmonics such as second-order harmonics, fourth-order harmonics, etc. with respect to the power fundamental frequency (50Hz). On the other hand, as shown in FIG. 14, in the signal obtained by performing band-pass filtering and envelope processing on the sinusoidal current signal including the discharge noise signal, the discharge noise signal appears as even-order harmonics such as second-order harmonics, fourth-order harmonics, etc. with respect to the power fundamental frequency.

The difference between the sinusoidal current waveforms shown in FIGS. 7 and 11 is the difference between a current signal generated with respect to a ground potential and a current signal having a constant potential. Comparing the results of frequency analysis shown in FIGS. 9 and 13, partial discharge signals appear as third and higher odd-order harmonics, whereas discharge noise appears as second and higher even-order harmonics.

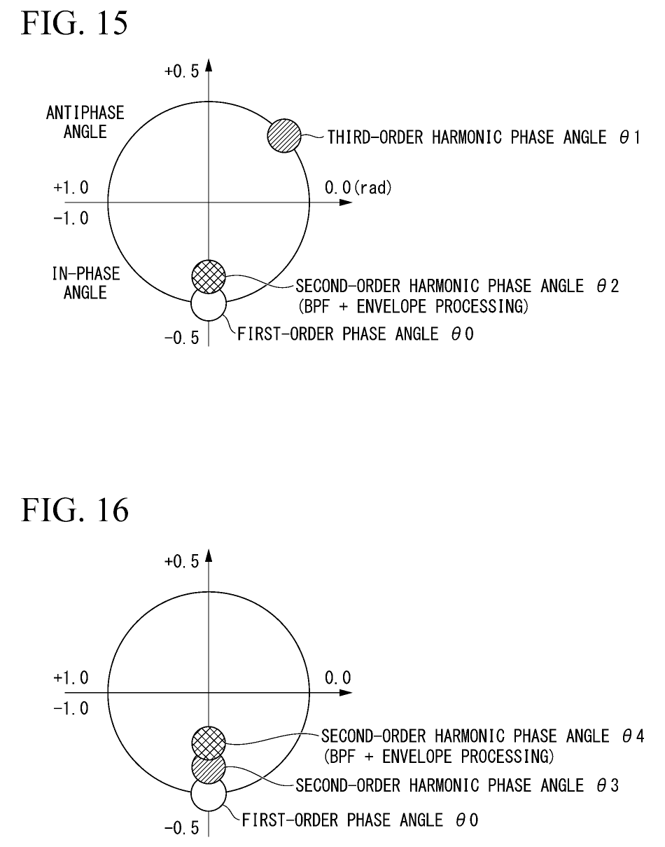

FIG. 15 is a diagram showing a phase angle of each harmonic when the partial discharge signal is included in the sinusoidal current signal. In FIG. 15, θ1 is the phase angle of the third-order harmonic appearing in the sinusoidal current signal including the partial discharge signal. θ2 is the phase angle of the second-order harmonic appearing in the signal obtained by performing band-pass filtering and envelope processing on the sinusoidal current signal including the partial discharge signal. For comparison, FIG. 15 also shows the phase angle θ0 of the power fundamental wave.

As shown in FIG. 15, the partial discharge signal appears in the sinusoidal current signal as an odd-order harmonic having a phase angle θ1 that is in antiphase with respect to the phase angle θ0 of the power fundamental wave. The phase angle θ1 is a phase angle of ±90 degrees or more with respect to the phase angle θ0 of the power fundamental wave. In a signal obtained by performing band-pass filtering and envelope processing on the sinusoidal current signal, the partial discharge signal appears as an even-order harmonic having a phase angle θ2 that is a phase angle of the same phase with respect to the phase angle θ0 of the power fundamental wave. The phase angle θ2 is a phase angle less than ±90 degrees with respect to the phase angle θ0 of the power fundamental wave.

FIG. 16 is a diagram showing a phase angle of each harmonic when the discharge noise signal is included in the sinusoidal current signal. In FIG. 16, θ3 is the phase angle of the second-order harmonic appearing in the sinusoidal current signal including the discharge noise signal. θ4 is the phase angle of the second-order harmonic appearing in the signal obtained by performing band-pass filtering and envelope processing on the sinusoidal current signal including the discharge noise signal. For comparison, FIG. 16 also shows the phase angle θ0 of the power fundamental wave.

As shown in FIG. 16, the partial discharge signal appears in the sinusoidal current signal as an even-order harmonic having a phase angle θ3 that is a phase angle of the same phase with respect to the phase angle θ0 of the power fundamental wave. In a signal obtained by performing band-pass filtering and envelope processing on the sinusoidal current signal, the partial discharge signal appears as an even-order harmonic having a phase angle θ4 that is a phase angle of the same phase with respect to the phase angle θ0 of the power fundamental wave.

As is clear from the above simulation analysis results, the partial discharge signal appears as the odd-order harmonic having a frequency that is odd multiples of the power fundamental wave, among the harmonics included in the sinusoidal current signal. Therefore, if the sinusoidal current signal includes the odd-order harmonic, it is inferred that a partial discharge has occurred. However, when odd-order harmonic noise is mixed into the sinusoidal current signal as disturbance noise, it is not possible to distinguish whether the odd-order harmonic contained in the sinusoidal current signal is a harmonic due to the partial discharge or a harmonic due to the disturbance noise as described above. On the other hand, the partial discharge signal appears as an odd-order harmonic having the first phase angle that is an antiphase angle with respect to the phase angle of the power fundamental wave. Therefore, by not only determining whether or not the sinusoidal current signal includes the odd-order harmonic but also determining whether or not the odd-order harmonic has the first phase angle, the partial discharge can be detected in distinction from the disturbance noise as described above.

When the odd-order harmonic noise having the first phase angle is mixed into the sinusoidal current signal, even if only the above determination is used, it is not possible to distinguish whether the odd-order harmonic included in the sinusoidal current signal is a harmonic due to the partial discharge or a harmonic due to external disturbance noise. In a signal (second signal) obtained by performing band-pass filtering and envelope processing on the sinusoidal current signal, the partial discharge signal appears as the even-order harmonic having the second phase angle that is in phase with the phase angle of the power fundamental wave. Therefore, by determining not only whether or not the odd-order harmonic included in the sinusoidal current signal has the first phase angle but also whether or not the even-order harmonic included in the second signal has the second phase angle, the partial discharge can be detected in distinction from the odd harmonic noise having the first phase angle.

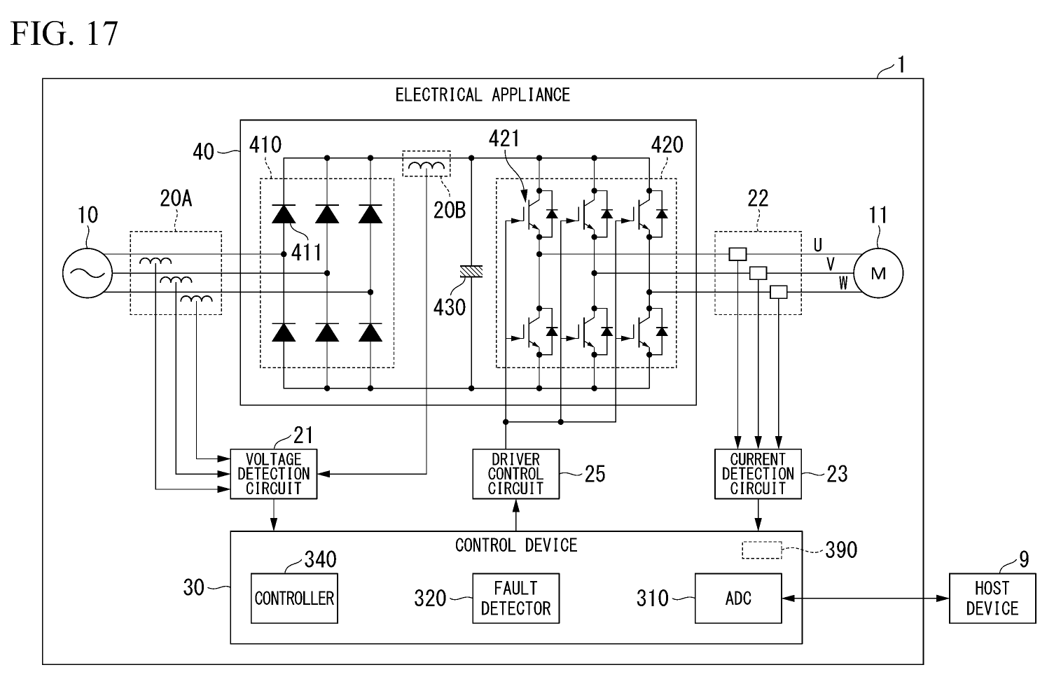

FIG. 17 is a diagram schematically showing a first modification example of the electrical appliance 1. As shown in FIG. 17, the first modification example of the electrical appliance 1 includes a power converter 40. The power converter 40 drives the three-phase induction motor 11 by converting the power from the three-phase AC power supply 10. The power converter 40 includes a rectifier circuit 410, a switching circuit 420, and a smoothing capacitor 430.

The rectifier circuit 410 rectifies the supplied AC voltage. The rectifier circuit 410 outputs the rectified voltage (DC voltage). The rectifier circuit 410 includes a plurality of diodes 411. Two diodes 411 are connected in series between the high potential side node and the low potential side node in the power converter 40. Two diodes 411 connected in series form a leg. A plurality of legs is connected in parallel to each other. The rectifier circuit 410 includes three legs corresponding to the U-phase, V-phase, and W-phase of the three-phase AC power supply 10.

The smoothing capacitor 430 smooths the voltage (DC voltage) output from the rectifier circuit 410. The smoothing capacitor 430 is connected in parallel to the rectifier circuit 410 and the switching circuit 420 between the high potential side node and the low potential side node in the power converter 40.

The switching circuit 420 converts the supplied DC voltage into an AC voltage. The switching circuit 420 includes a plurality of switching elements 421. The switching element 421 includes an IGBT (Insulated Gate Bipolar Transistor) and a diode. Two switching elements 421 are connected in series between a high potential side node and a low potential side node in the power converter 40. Two switching elements 421 connected in series form a leg. A plurality of legs is connected in parallel to each other. The switching circuit 420 includes three legs corresponding to the U-phase, V-phase, and W-phase of the three-phase induction motor 11.

Power converter 40 may include other components such as a DC reactor (not shown).

The three-phase AC power supply 10 is connected to the rectifier circuit 410 of the power converter 40. Wiring of each phase of the three-phase AC power supply 10 is connected to a corresponding one of three legs of the rectifier circuit 410.

The three-phase induction motor 11 is connected to the switching circuit 420 of the power converter 40. The wiring of each phase of the three-phase induction motor 11 is connected to a corresponding one of the three legs of the switching circuit 420.

The voltage sensor circuit 20A senses the state of the voltage signal of each phase of the three-phase AC power supply 10. The voltage sensor circuit 20A monitors the input power supply voltage.

The voltage sensor circuit 20B senses the state of the DC voltage output from the rectifier circuit 410. The voltage sensor circuit 20B monitors the rectified DC voltage.

The voltage detection circuit 21 transmits to the control device 30 a voltage signal indicating the sensed result of the voltage sensor circuits 20A and 20B. The voltage signal is an analog signal.

The current sensor circuit 22 senses the drive current output from the switching circuit 420. The current sensor circuit 22 monitors the value of the drive current supplied to the three-phase induction motor 11.

The current detection circuit 23 transmits a current signal indicating the sensed result of the current sensor circuit 22 to the control device 30. The current signal is an analog signal.

The driver control circuit 25 generates a PWM (Pulse Width Modulation) signal or a PAM (Pulse Amplitude Modulation) signal in accordance with an instruction from the control device 30. The driver control circuit 25 sends the PWM signal or the PAM signal to each switching element 421 of the switching circuit 420. As a result, the driver control circuit 25 drives the switching element 421 of the switching circuit 420. The driver control circuit 25 is connected to the gate (control terminal) of each switching element 421.

The control device 30 converts the analog signals transmitted from the voltage detection circuit 21 and the current detection circuit 23 into digital signals using the ADC 310. The obtained digital signals are used to control the power converter 40.

The control device 30 generates a command signal for controlling the rotation state of the three-phase induction motor 11 in accordance with a command from the host device 9. The control device 30 transmits the generated command signal to the driver control circuit 25. As a result, the control device 30 controls the operation of the three-phase induction motor 11 via the driver control circuit 25.

The fault detector 320 of the control device 30 obtains digital signals corresponding to the sensed result of the voltage sensor circuits 20A and 20B, and a digital signal corresponding to the sensed result of the current sensor circuit 22. As a result, the fault detector 320 constantly monitors the state of the power converter 40 and the state of the three-phase induction motor 11.

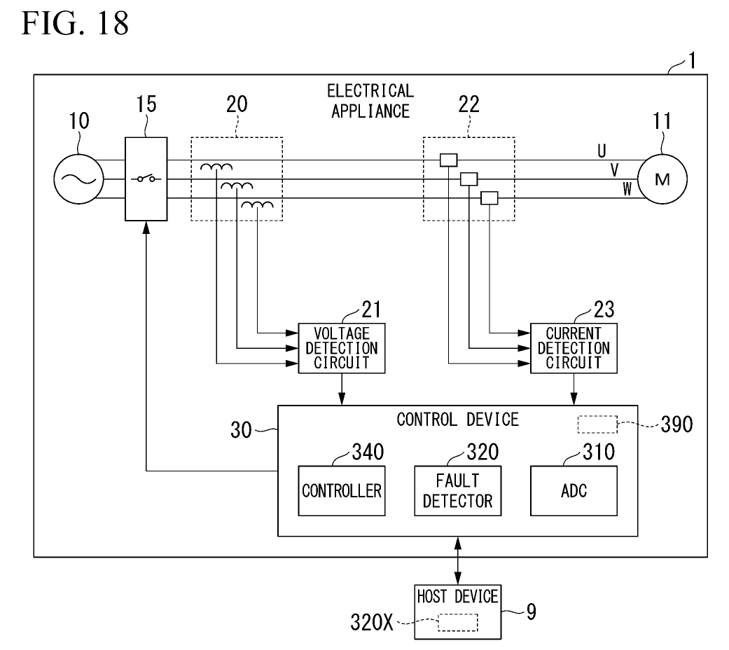

FIG. 18 is a diagram schematically showing a second modification example of the electrical appliance 1. As shown in FIG. 18, the host device 9 may execute the process of detecting partial discharge instead of the fault detector 320. That is, the fault detector 320 in the electrical appliance 1 only has the function of communicating various electric signals to the host device 9 in the electrical appliance 1.

As shown in FIG. 18, the host device 9 includes a fault detector 320X. The host device 9 executes various processes for detecting partial discharge using the fault detector 320X based on signals from the fault detector 320 of the electrical appliance 1.

This allows the host device 9 to grasp the fault state within the electrical appliance 1 from outside the electrical appliance 1. Therefore, the host device 9 functions as a control device for the three-phase induction motor 11 and the electrical appliance 1. In the host device 9, the various functions implemented as the fault detector 320 are implemented and operated by software as algorithms and analysis methods.

This reduces the computational load of the edge device (electrical appliance 1) in a system (network) including the electrical appliance 1 and the host device 9. When the functions for performing the various processes for detecting partial discharge described above are implemented in an existing system, as in this modified example, the host device 9 capable of performing partial discharge detection processes can operate the entire system in a highly scalable state without adding a fault detector 320 to existing electrical appliance.

According to at least one embodiment described above, it is possible to provide a control device including a controller configured to control an electric motor, and a fault detector configured to detect a fault of the electric motor, wherein the fault detector is configured to: perform a frequency analysis of a voltage signal and a current signal that drive the electric motor; determine, based on a result of the frequency analysis, whether or not the current signal includes an odd-order harmonic having a frequency that is odd multiples of a fundamental wave of the voltage signal; and determine, based on the result of the frequency analysis, whether or not the odd-order harmonic has a first phase angle that is a phase angle of an opposite phase with respect to a phase angle of the fundamental wave, so that partial discharge can be detected by distinguishing them from noise.

The functionality of the elements disclosed herein may be implemented using circuitry or processing circuitry which includes general purpose processors, special purpose processors, integrated circuits, ASICs (“Application Specific Integrated Circuits”), FPGAs (“Field Programmable Gate Arrays”), conventional circuitry and/or combinations thereof which are programmed, using one or more programs stored in one or more memories, or otherwise configured to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A control device comprising:
a controller configured to control an electric motor; and
a fault detector configured to detect a fault of the electric motor,
wherein the fault detector is configured to:
perform a frequency analysis of a voltage signal and a current signal that drive the electric motor;
determine, based on a result of the frequency analysis, whether or not the current signal includes an odd-order harmonic having a frequency that is odd multiples of a fundamental wave of the voltage signal; and
determine, based on the result of the frequency analysis, whether or not the odd-order harmonic has a first phase angle that is a phase angle of an opposite phase with respect to a phase angle of the fundamental wave.

2. The control device according to claim 1, wherein
the odd-order harmonic is a third-order harmonic having a frequency that is three multiples of the fundamental wave.

3. The control device according to claim 1, wherein
the first phase angle is a phase angle of ±90 degrees or more with respect to the phase angle of the fundamental wave.

4. The control device according to claim 1, wherein
the fault detector is further configured to output a partial discharge detection signal indicating that a partial discharge in the electric motor is detected when the odd-order harmonic has the first phase angle.

5. The control device according to claim 1, wherein
the fault detector is further configured to:
extract a first signal in a first frequency band from the current signal;
generate a second signal by performing envelope processing on the first signal;
perform a frequency analysis of the second signal;
determine, based on a result of the frequency analysis of the second signal, whether or not the second signal includes an even-order harmonic having a frequency that is even multiples of the fundamental wave; and
determine, based on the result of the frequency analysis of the second signal, whether or not the even-order harmonic has a second phase angle that is a phase angle of the same phase with respect to the phase angle of the fundamental wave.

6. The control device according to claim 5, wherein
the even-order harmonic is a second-order harmonic having a frequency that is two multiples of the fundamental wave.

7. The control device according to claim 5, wherein
the second phase angle is a phase angle less than ±90 degrees with respect to the phase angle of the fundamental wave.

8. The control device according to claim 5, wherein
the fault detector is further configured to output a partial discharge detection signal indicating that a partial discharge in the electric motor is detected when the odd-order harmonic has the first phase angle and the even-order harmonic has the second phase angle.

9. An electrical appliance comprising:
an electric motor connected to a power supply; and
the control device according to claim 1, wherein the control device controls the electric motor.

10. A fault detection method comprising:
performing a frequency analysis of a voltage signal and a current signal that drive an electric motor;
determining, based on a result of the frequency analysis, whether or not the current signal includes an odd-order harmonic having a frequency that is odd multiples of a fundamental wave of the voltage signal; and
determining, based on the result of the frequency analysis, whether or not the odd-order harmonic has a first phase angle that is a phase angle of an opposite phase with respect to a phase angle of the fundamental wave.
